(19) United States
(12) Patent Application Publication
(10) Pub. No.: US 2025/0189888 A1
(43) Pub. Date: Jun. 12, 2025

(54) PHOTOACTIVABLE HYBRID ORGANIC-INORGANIC SOL-GEL RESIN FOR 3D PRINTING

(71) Applicants: TOTALENERGIES ONETECH, Courbevoie (FR); CENTRE NATIONAL DE LA RECHERCHE SCIENTIFIQUE, Paris (FR); ECOLE NORMALE SUPERIEURE DE LYON, Lyon (FR); UNIVERSITE CLAUDE BERNARD LYON 1, Villeurbanne (FR)

(72) Inventors: Enric SANTANACH CARRERAS, Louey (FR); Laura Piedad CHIA GOMEZ, Lyon (FR); Stéphane PAROLA, Jonage (FR); Akos BANYAS, Villeurbanne (FR)

(21) Appl. No.: 18/845,397

(22) PCT Filed: Mar. 10, 2022
(86) PCT No.: PCT/IB2022/000132

§ 371 Date: Sep. 9, 2024

(51) Int. Cl. G03F 7/031; B29C 64/124; B29C 64/314; B29K 33/00; B29K 63/00; B29K 105/00; B29K 505/00; B29L 31/52; B33Y 10/00; B33Y 40/10; B33Y 70/10; C08F 2/50; C08G 73/06; C08L 79/04; C08L 83/08

(52) U.S. Cl. CPC G03F 7/031; B29C 64/124; B29C 64/314; B33Y 10/00; B33Y 40/10; B33Y 70/10; C08F 2/50; C08G 73/0688; C08L 79/04; C08L 83/08; B29K 2033/12; B29K 2063/00; B29K 2105/0005; B29K 2105/0061; B29K 2105/0094; B29K 2505/00; B29L 2031/52

(57) ABSTRACT

The invention relates to a photoactivable hybrid organic-inorganic sol-gel resin comprising
a) A sol-gel resin obtainable by a method comprising the steps of:
   a₁) Hydrolyzing at least one sol-gel precursor, said sol-gel precursor comprising:
      An organic polymerizable moiety (A), and
      An inorganic polymerizable moiety (B),
   and
   a₂) Condensing the obtained hydrolyzed precursor(s);
b) Photoactivators comprising:
   a radical photoinitiator, able to initiate a one-photon polymerization at a first irradiation wavelength (λ₁), and
   a photobase, able to initiate a two-photon polymerization at a second irradiation wavelength (λ₂),
   said photoactivators being homogeneously dispersed in said sol-gel resin a).

### TECHNICAL FIELD

The present invention relates to a photoactivable hybrid organic-inorganic sol-gel resin and its use for preparing a photopatterned structure, by photopolymerization, notably by 3D printing, more particularly by UV maskless projection lithography and/or 3D two-photon direct laser writing (2P DLW).

The invention also relates to a method for preparing a photopatterned structure and to the photopatterned structures obtainable by this process.

### BACKGROUND ART

Sol-gel technology is based on versatile chemistry that allows the preparation of glassy and ceramic materials under mild chemical conditions. Following this approach, materials are obtained in the form of powders, thin films, fibres and monoliths from molecular precursor solutions. One major characteristic of the sol-gel process is the use of low temperatures (<100° C.) to carry out involved chemical reactions so that evaporation losses and phase transformations are minimized. Sol-gel materials are chemically, thermally and mechanically stable; therefore, they are of great interest for optical, thermal insulation, photocatalysis and biological applications.

According to their synthesis route, they can be classified into (1) particulate and (2) polymerized sol-gel materials. The former is characterized by a highly microporous structure that is mainly determined by the size and geometry of dispersed silica particles in aqueous solutions, while the latter is obtained mostly through hydrolysis and condensation of polymeric silicon or metal alkoxide solutions.

In the case of polymerized sol-gels, materials with very different structures at molecular-scale can be synthesized in acid or base-catalyzed hydrolysis-condensation reactions from either one or multiple alkoxide precursors. Moreover, organic or bioactive groups can be integrated or trapped within the pores of silicon or metal oxide sol-gel materials (e.g. SiO₂, ZrO₂, Al₂O₃, TiO₂) to synthesize materials with superior properties. For example, sol-gel materials with improved anticorrosive or hydrophilic properties opening up novel fields of applications, such as in drug delivery, have been disclosed.

Sol-gel derived ORganically MOdified CERamic (ORMOCER®) materials have probably been the most widely studied and chemically engineered in this category over the last twenty years. They are composed of a solid silica matrix with chemically bonded organic components providing similar properties as inorganic silicate glasses (e.g. hardness and transparency) that can be tailored by the type and concentration of organic used. Even more interesting, doping of their inorganic matrix with photoactive organic groups enables ORMOCER® materials to be polymerized not only by thermal but also by light-initiated reactions.

Accordingly, conventional UV lithography techniques have been already used to synthesize them in the form of functional optical devices in 2D and 2.5D, such as waveguides or microlenses. Similarly to organic SU-8 resins, ORMOCER® materials behave as negative tone photoresists. Hence, they solidify as soon as the sol-gel transition is completed upon irradiation at a specific wavelength. For that purpose, additional photoactive molecules (e.g. photoinitiators and/or photosensitizers) are added to transform organic-inorganic hybrid resin into a photoactivable one.

Nowadays, organic-inorganic sol-gel hybrid materials are also responding to the increasing demand of the 3D printing industry for novel functional materials, in particular suitable for 3D printing techniques based on light-matter interaction, and in which light-initiated cross-linking of materials occurs throughout printing.

Thus, 3D print sol-gel organo-ceramic materials suitable for Digital Light Processing (DLP), enable the printing of large 3D objects on a layer-by-layer basis, that is from a millimeter (mm) up to a meter (m) scale, but only with a macroscale resolution.

On the other hand, 3D printed sol-gel organo-ceramic materials suitable for the two-photon absorption induced stereolithography (TPS), also referred to as direct laser writing (2P DLW), which is a high-resolution 3D printing technique based on the non-linear absorption of light, enable printing of micrometer size objects with nanometric resolution.

However, if many functional microdevices have been fabricated using the two-photon 2P DLW technique, from silica- and metal-based organic-inorganic sol-gel materials, large 3D printed surfaces (>dm²) are still not systematically attainable through this technique.

Thus, there is a need to provide a photoactivable organic-inorganic sol-gel material compatible with both one-photon and two-photon polymerization, such as UV-maskless lithography and 2P DLW respectively, enabling precise and fast fabrication of macroscopic three-dimensional structures featuring microscale and nanoscale characteristics.

### SUMMARY OF THE INVENTION

A first aspect of the present disclosure relates to a photoactivable hybrid organic-inorganic sol-gel resin comprising:
a) A sol-gel resin obtainable by a method comprising the steps of:
   a₁) Hydrolyzing at least one sol-gel precursor, said sol-gel precursor comprising:
      An organic polymerizable moiety (A), and
      An inorganic polymerizable moiety (B),
   and
   a₂) Condensing the obtained hydrolyzed precursor(s);
b) Photoactivators comprising:
   a radical photoinitiator, able to initiate a one-photon polymerization at a first irradiation wavelength (λ₁), and
   a photobase, able to initiate a two-photon polymerization at a second irradiation wavelength (λ₂),
   said photoactivators being homogeneously dispersed in said sol-gel resin a).

This photoactivable sol-gel resin is particularly advantageous for 3D printing as it is compatible with both one-photon polymerization, such as UV maskless projection lithography, and two-photon polymerization, such as direct laser writing (2P DLW).

Thus, this photoactivable sol-gel resin advantageously enables to prepare large 2.5D photopatterned surfaces (cm² to dm²) and high-resolution 3D microstructures fabricated from a single material.

As a further advantage, the absorption properties of the photoactivable material can be adapted to different light irradiation sources or 3D printing setups, notably through the selection of photoinitiator and/or the photobase.

In addition, the photoactivable sol-gel resin can be advantageously prepared by complete hydrolysis and partial condensation of the precursor using a Fast Sol-Gel (“FSG”) process, to get UV-curable materials with low organic content enabling a solidification with limited shrinkage and without formation of cracks once the sol-gel resin is photopatterned by curing, high optical transparency and high adhesive strength, high temperature stability, as well as adaptable opto-mechanical properties.

In particular, the sol-gel resin prepared according to the FSG process does not require the use of any additional volatile solvent, so that the reproducibility and repeatability of the two-photon polymerization of the photoactivable sol-gel resin, notably via 2P DLW, is strongly improved.

In a second aspect, the present disclosure relates to the use of a photoactivable hybrid organic-inorganic sol-gel resin as defined above for preparing a photopatterned structure, by 2D and/or 3D photopolymerization, notably by 2D photolithography or by 3D printing.

Another aspect of the present invention relates to a method for preparing a photopatterned structure from a photoactivable hybrid organic-inorganic sol-gel resin as defined above comprising the steps of:
i. Providing a photoactivable hybrid organic-inorganic sol-gel resin as defined above;
ii. Photopatterning the sol-gel resin, thereby obtaining a cured sol-gel resin based material,
iii. Optionally removing the uncured sol-gel resin, if present; and
iv. Recovering the obtained photopatterned structure.

Still another aspect of the present disclosure relates to a photopatterned structure obtainable by the process as described above.

### BRIEF DESCRIPTION OF THE FIGURES

FIG. 1 A) Projection system used for the one-photon induced UV maskless lithography; B) Jablonski diagram of the absorption process of light at 385 nm.

FIG. 2 A) Schematic of the setup used for the two-photon induced 3D Direct Laser Writing; B) Jablonski diagram of the absorption of light at 532 nm.

FIG. 3 UV maskless lithography of photoactivable hybrid organic-inorganic sol-gel resin (A) [4 s, 10× objective] and (B) [60 s, 2.5× objective].

FIG. 4 3D-printed hybrid organic-inorganic sol-gel material (A) scaffold and (B) woodpile structures by direct laser writing.

FIG. 5 (A) UV photopatterned sol-gel chessboard, (B) 3D-printed sol-gel chess pieces, (C)-(D) Chess set from hybrid organic-inorganic sol-gel resin.

FIG. 6. SEM images of Ti/Si=0.3 (molar ratio) woodpile structures fabricated by DLW a constant laser power of 0.45 mW and a constant exposure time of (A) 5 ms (B) and 10 ms.

FIG. 7 SEM images of Ti/Si=0.15 (molar ratio) woodpile structures fabricated by DLW a constant laser power of 0.29 mW and a constant exposure time of (A) 10 ms (B) and 20 ms

### DETAILED DESCRIPTION

The invention is now described in more detail and in a non-limiting manner in the following description.

The following terms and expressions contained herein are defined as follows.

The expression “sol-gel” is understood in the present disclosure to mean a network which is formed from solution by a progressive change of liquid precursor(s) into a sol (colloidal system) and then into a gel (non-fluid colloidal network or polymer network that is expanded throughout its whole volume by a fluid).

The expression “sol-gel resin” means a material that is obtained from a sol-gel precursor, and which can be either in the form of a sol, notably before photoactivation, or in the form of a gel or of a solid after photoactivation.

As used herein, the terms “hybrid organic-inorganic sol-gel resin” refer to a material, obtained by partial hydrolysis-condensation of at least one sol-gel precursor containing both at least one polymerizable organic moiety (A) and at least one polymerizable inorganic moiety (B). The polymerizable inorganic moiety (B) may be polymerized by hydrolysis and condensation. In fact, before being photoactivated, notably photopatterned or photopolymerized, the photoactivable sol-gel resin is in the form of a sol. Once it is photopolymerized, the photoactivable sol-gel resin is in the form of a solid.

As used herein, the term “C₁-Cₙ alkyl” refers to a linear, branched or cyclic alkyl group, having 1 to n carbon atoms (CₙH₂ₙ₊₁). Suitable alkyl groups include methyl, ethyl, n-propyl, i-propyl, n-butyl, i-butyl, s-butyl and t-butyl, pentyl and its isomers (e.g. n-pentyl, iso-pentyl), and hexyl and its isomers (e.g. n-hexyl, iso-hexyl).

As used herein, the term “C₁-Cₙ alkoxy” refers to an (C₁-Cₙ alkyl)—O— group wherein the alkyl group has the same meaning as alkyl defined above.

As used herein, the term “alkylene” refers to a substituted or unsubstituted, branched or straight chained hydrocarbon of 1 to 6 carbon atoms, which is formed by the removal of two hydrogen atoms. A designation such as “C₁-C₄ alkylene” refers to an alkylene radical containing from 1 to 4 carbon atoms. Examples include methylene (—CH₂—), 1,2-ethandiyl (—CH₂CH₂—), etc.

As used herein, the term “acryloxy” refers to a group CH₂═CH—C(═O)O—, and “methacryloxy” to a group CH₃— CH═CH—C(═O)O—.

As used herein, the term “glycidoxy” refers to a group Epoxy-CH₂—O—.

All other terms used in the description of the present invention have their meanings as is well known in the art.

### Photoactivable Hybrid Organic-Inorganic Sol-Gel Resin

A first aspect of the present disclosure relates to a photoactivable hybrid organic-inorganic sol-gel resin comprising:
a) A sol-gel resin obtainable by a method comprising the steps of:
   a₁) Hydrolyzing at least one sol-gel precursor, said sol-gel precursor comprising:
      An organic polymerizable moiety (A), and
      An inorganic polymerizable moiety (B),
   and
   a₂) Condensing the obtained hydrolyzed precursor(s);
b) Photoactivators comprising:
   a radical photoinitiator, able to initiate a one-photon polymerization at a first irradiation wavelength (λ₁), and
   a photobase, able to initiate a two-photons polymerization at a second irradiation wavelength (λ₂),
   said photoactivators being homogeneously dispersed in said sol-gel resin.

### Sol-gel a)

The sol-gel precursor preferably comprises an inorganic polymerizable moiety (B) which is a metal alkoxide group of formula (I_{B}):

M(OR′) (IB)
wherein
M is a metal, notably selected from Si, Ti, Zr, Al, Sn, preferably Si; and
R′ is a C₁-C₆ alkyl group.

Preferably, the organic polymerizable moiety (A) is a (meth)acryloyloxy (H₂C═CH(Me)—(C═O)O—) or an epoxy group.

In a preferred embodiment, the sol-gel precursor is a compound of formula (I):

RₙM(OR′)₄₋ₙ (II)
wherein
M is a metal, notably selected from Si, Ti, Zr, Al, Sn, preferably Si;
n is 1, 2 or 3, preferably 1 or 2,
R′ is a C₁-C₆ alkyl group
R is —X-A
X is a C₁-C₆ alkylene group,
A is an acryloxy, methacryloxy, epoxy or glycidoxy group, preferably an acryloxy, or methacryloxy, group.

In a preferred embodiment, the sol-gel precursor is of a compound of formula (II)

RₙSi(OR′)₄₋ₙ (II)
wherein
n is 1, 2 or 3, preferably 1 or 2,
R′ is a C₁-C₆ alkyl group
R is —X-A
X is a C₁-C₆ alkylene group,
A is a an acryloxy, methacryloxy, epoxy or glycidoxy group, preferably an acryloxy, or methacryloxy, group.

The sol-gel precursor may be notably selected from 3-acryloxypropyl trimethoxysilane (APTMS), 3-methylacryloxypropyl trimethoxy silane (MAPTMS), tetra(acryloxy-ethoxy)silane, 3-methacryloxypropyl methyldimethoxysilane, 3-methacryloxypropyl methyldiethoxysilane, 3-glycidoxypropyl triethoxysilane, 3-glycidoxypropyl trimethoxysilane, 3-glycidoxypropyl methyldimethoxysilane, 3-glycidoxypropyl methyldiethoxysilane.

The photoactivable hybrid organic-inorganic sol-gel resin includes a sol-gel matrix which is prepared by a method comprising 3 steps a1, and a2), notably by a fast sol gel process.

The sol-gel resin a) is notably a sol-gel resin which has not reached the gel point, that is a sol-gel resin wherein the hydrolyzed precursor is only partially condensed. Thus, the sol-gel a) is notably a sol.

### Step a₁)

In step a₁), the sol-gel precursor is hydrolysed, notably in the presence of an acidic or basic aqueous solution. Preferably, the sol-gel precursor is hydrolysed by using an acidic solution, such as a hydrochloric acid solution. Indeed, the acidic conditions generally better promotes the hydrolysis reaction of the sol-gel precursor which can undergo a condensation in a second step.

This step enables to partially or totally hydrolyzes the inorganic polymerizable moiety (B) such as M-OR′ into M-OH, notably Si—OR′ into Si—OH, while alcohol molecules R′OH are released during the reaction.

M-OR′+H₂O->M-OH+R′—OH

According to a preferred embodiment, no organic solvent is added to the acidic or basic aqueous solution in step a₁). The alcohol R′OH produced during the hydrolysis of the sol-gel precursor is thus the only organic solvent.

### Step a2)

The obtained hydolyzed inorganic polymerizable moieties (B), such as M-OH then polymerize by condensation to form M-O-M bonds.

Thus silanols (Si—OH) then react with each other through a condensation reaction, (O—Si—O) siloxane bonds are formed and water and/or alcohol is released.

M-OH+YO-M->M-O-M+R′—OH(Y is H or R′)

Hydrolysis is followed by the condensation: the condensation starts as soon as the functions are hydrolyzed so that steps a₁) and a₂) cannot be separated. The obtained sol is totally hydrolyzed but condensation remains partial due to a low condensation kinetik.

Both steps may be performed by heating the hydrolyzed precursor at a temperature comprised in the range of 60° C. to 80° C., generally under stirring.

### Step a₃)

After steps a₁) and a₂), the method for preparing the sol-gel may further include, a step a₃) of:
a₃) At least partially removing one or more side products of the hydrolysis reaction,
In step a₃), one or more side products of the hydrolysis and condensation reactions, notably water and alcohol, are at least partially removed.

This embodiment including step a₃) is particularly preferred as it enables to improve the reproducibility of the subsequent 3D printing of the photoactivable sol-gel.

The side products may be removed by vacuum distillation.

The viscosity of the sol-gel precursor increases due to the generation of partially condensed structures during the process steps a₂) and optionally a₃), without reaching the gel point. Thus, in step a₂) the hydrolyzed precursor is only partially condensed.

The viscosity of the sol-gel precursor increases with the condensation (CD) degree which may be monitored and calculated by NMR.

The condensation degree (CD) is herein understood as the ratio of the number of condensed bond, for example Si—O—Si, relative to the number of condensable bonds, for example —Si(OR′)₄₋ₙ.

Thus, it is desirable not to reach the gel point of the sol-gel resin and to stop the reaction before all the condensable bonds are effectively condensed. Indeed, the condensation will be subsequently completed during the photoactivation of the photoactivable sol-gel resin, notably during photolithography or 3D printing.

The temperature of steps a₁) and a₂) may be lowered so as to slow down or even stop the hydrolysis and/or condensation reactions before reaching the gel point. As an example, the condensation reaction may be stopped by storing the sol-gel a) or the photoactivable sol-gel at a temperature of 4° C.

Thus, the sol-gel obtainable after step a₂) or optionally step a₃) may have a condensation ratio greater than or equal to 40%, preferably greater than or equal to 75%, preferably between 50 and 90%, and more preferably between 70 and 90%.

Thus, this sol-gel resin may have a high condensation ratio, without gelation.

In other words, the sol-gel resin obtained after step a₂) or step a₃) is preferably a sol.

For alkoxysilane precursors, the condensation ratio can be determined by ²⁹Si-NMR. This technique is commonly used to study kinetics and mechanisms of the hydrolysis-condensation reactions before the gel point is reached.

The sol-gel resin obtainable after step a₃) has a viscosity superior or equal to 10 cPs, preferably between 10 and 8000 cPs, more preferably between 300 and 6000 cPs.

### Photoactivators b)

The photoactivable hybrid organic-inorganic sol-gel resin also comprises photoactivators.

As used herein, the term “photoactivator” means a molecule that creates reactive species, such as free radicals, cations or anions, when exposed to a UV or visible radiation, such reactive species being able to activate the polymerization of the sol-gel a), more specifically the polymerization of the partially hydrolyzed and/or condensed precursor.

The photoactivators are homogeneously dispersed in the hydrolyzed sol-gel precursor, which means that no aggregates and/or solid particles are visible to the naked eye.

The homogenization of the photoactivators into the sol-gel resin may be obtained by stirring, notably by any conventional method.

As used herein, the terms “radical photoinitiator” means a photoactivator that generates free radicals when activated, which means when exposed to an irradiation wavelength (λ₁).

More specifically, the radical photoinitiator incorporated in the photoactivable sol-gel resin is able to absorb one-photon at the irradiation wavelength (λ₁), thereby generating free radical species, that will induce a one-photon polymerization of the sol a), notably of the organic polymerizable moiety (A).

The radical photoinitiator may be a Norrish Type I photoinitiator or Norrish Type II photoinitiator, preferably a Norrish Type I photoinitiator.

As used herein, the term “photobase” means a photoactivator that generates a base when activated, that is when exposed to an irradiation wavelength (λ₂).

More specifically, the photobase incorporated in the photoactivable sol-gel resin is able to absorb two-photons at the irradiation wavelength (N₂), thereby releasing a base, that will induce a two-photon polymerization of the sol-gel resin a), notably of the hydrolyzed and partially condensed inorganic polymerizable moiety (B), so as to complete the inorganic condensation of sol-gel resin a).

Without willing to be bound to any particular theory, high-resolution 3D printing is assumed to proceed by a local pH change, at the micrometer scale, of the reaction medium upon irradiation of the photobase.

The photoinitiator and/or the photobase may be selected according to the wavelengths (λ₁) or (λ₂) of the irradiation source.

The irradiation source may be a light-emitting diode with an emission peak centered at (λ₁) and/or a pulse laser beam centered at (λ₂). Advantageously, the photoactivable sol-gel resin may be activated by irradiation with both sources, both at (λ₁) and at (λ₂), either sequentially or simultaneously.

The radical photoinitiator may comprise a maximum absorption wavelength comprised in the range of emission wavelengths of the light emitting diode.

The radical photoinitiator may be an acyl phosphine oxide, notably selected from 2,4,6-trimethylbenzoyldiphenyl phosphine oxide, phenylbis(2,4,6-trimethylbenzoyl)phosphine oxide (BAPO).

The photobase preferably comprises a maximum absorption wavelength comprised in the range of emission wavelength of the source of λ₂.

In other words, the two-photon absorption spectrum of the photobase overlaps with λ₂.

The photobase may comprise a maximum absorption wavelength comprised in the range of a pulse laser beam, notably at 515, 532, 700, or 900 nm.

The photobase may release, when activated, a base having a pKa superior to 11, such as a base selected from DBU (1,8-diazabicyclo [5.4.0]undec-7-ene), or TBD (1,5,7-triazabicyclo[4.4.0]dec-5-ene.

The photobase may be selected from PBG1 or PBG2 as disclosed in Bouzrati-Zerelli, Mariem, et al. “Design of novel photobase generators upon violet LEDs and use in photopolymerization reactions” Polymer 124 (2017): 151-156.

These photobases are built on a near-UV and visible light sensitive (E)-3-(2,2′-bithiophen-5-yl)-2-cyanoacrylic acid chromophore and a latent strong base such as 1,8-diazabicyclo[5.4.0]undec-7-ene (DBU) and 1,5,7-triazabicyclo[4.4.0]dec-5-ene (TBD). Upon irradiation, it has been shown that decarboxylation occurs and the base is released.

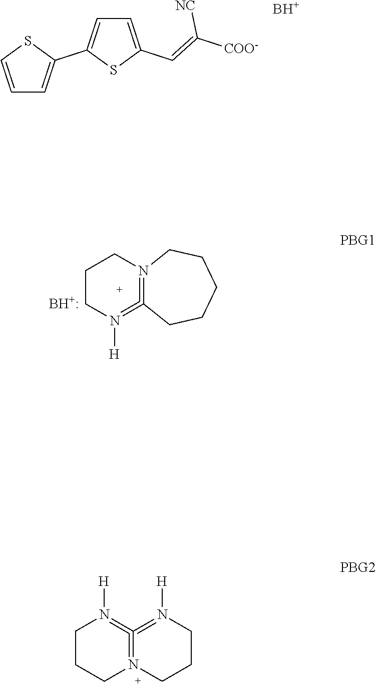

The molar ratio of the radical photoinitiator relative to the sol-gel precursor may be comprised in the range of 10⁻⁴ and 10⁻², preferably between 10⁻³ and 4×10⁻³. The molar ratio of the photobase relative to the sol-gel precursor may be comprised in the range of 10⁻⁴ and 10⁻², preferably between 10⁻³ and 4×10⁻³.

The molar ratio of the radical photoinitiator/photobase may be comprised in the range of [0.01]and [10], preferably between [0.5]and [4.0]

According to a preferred embodiment, the photoactivable hybrid organic-inorganic sol-gel resin comprises:
a) A sol-gel resin obtainable according to steps a₁) and a₂) as defined above from a compound of formula (II) or (I), notably APTMS, as a sol-gel precursor, and
b) Photoactivators comprising:
   2,4,6-Trimethylbenzoylphenylphosphinic acid ethyl ester, as a radical photoinitiator,
   PBG1 as a photobase,
   said photoactivators being homogeneously dispersed in said sol-gel resin.

### Use of the Photoactivable Hybrid Organic-Inorganic Sol-Gel Resin

According to second aspect, the present disclosure relates to a use of a photoactivable hybrid organic-inorganic sol-gel resin as defined above for preparing a photopatterned structure, that is by photopolymerization, notably 2D or 3D photopatterning, such as UV maskless projection lithography, or 3D printing, in particular 3D two-photon direct laser writing (2P DLW).

In contrast to standard UV photolithography based on linear light absorption, 3D direct laser writing (2P DLW) is based on a non-linear absorption process whereby two photons occupying the same place at the same time are simultaneously absorbed in a single event. As a result, the molecule is excited from a lower energy level to a higher energy level passing through a virtual intermediate state.

The two-photon induced chemical reactions are confined in a 3D volume of typically less than 1 μm³ when a high-power laser (energy dose in the order of TW/cm²) is focused through a high numerical-aperture (NA) objective. The sub-micrometer resolution, related to the size of the polymerized volume or voxel (for volumetric pixel), and the short reaction times (<1 ms) are characteristics of two-photon stereolithography. Details of 3D microfabrication using two-photon absorption may be consulted elsewhere in literature (Baldacchini, T. Three-Dimensional Microfabrication Using Two-Photon Polymerization: Fundamentals, Technology, and Applications; William Andrew, 2015). A schematic of the two-photon direct laser writing system is presented in the experimental section.

Method for Preparing a Photopatterned Structure from the Photoactivable Hybrid Organic-Inorganic Sol-Gel Resin

In another aspect, the invention relates to a method for preparing a photopatterned structure from a photoactivable hybrid organic-inorganic sol-gel resin comprising the steps of:
i. Providing a photoactivable hybrid organic-inorganic sol-gel resin as defined above;
ii. Photopatterning the sol-gel resin, thereby obtaining a cured sol-gel resin based material,
iii. Optionally removing the uncured sol-gel resin, if present; and
iv. Optionally drying the cured sol-gel resin based material;
v. Recovering the obtained photopatterned structure.

### Step ii)

Step ii) consists in photopatterning a volume of the sol-gel resin. The photopatterning can be done by:
applying a pattern, in particular applying a physical mask, or preferably by projecting a 2D or 3D pattern and
irradiating the sol-gel resin to induce its curing according to the applied pattern, in particular the physical mask or the projected pattern or model.

The 2D pattern may be projected via a Digital Micromirror Device (DMD) or an LCD screen.

DMD consists of a rectangular array of micromirrors that correspond to individually switchable pixels that are focused on the sample. Resulting bright and dark dots correspond to exposed and unexposed regions on the sample.

The replacement of a physical mask used in conventional optical lithography

with a DMD is advantageous as direct contact and time-consuming alignment of the distance between photomask and photoresist are avoided.

The 3D pattern may be a CAD (“Computer Aided Design”) model which represents the object to be manufactured.

Step ii) therefore results in the formation of a cured sol-gel resin based material, which is generally solid.

Step ii) preferably comprises the step of irradiating the sol-gel resin at a wavelength:
(λ₁), so as to activate the radical photoinitiator, thereby inducing the cross-linking of the organic polymerizable moiety (A), and/or
(λ₂), so as to activate the photobase thereby inducing the condensation completion of the hydrolyzed polymerizable moiety (B) and possibly activate simultaneously the radical polymerization

Both irradiations at λ₁ and λ₂ can be performed either sequentially in any order, or simultaneously.

According to a preferred embodiment, step ii) is performed by:
One-photon polymerization at (λ₁), notably by UV maskless lithography and
Two-photon polymerization at (λ₂), notably by Direct Laser Writing at (λ₂).
   Step iii)

Step iii) consists in removing the uncured sol-gel resin, if present. Indeed, according to the pattern which has been used during photopatterning in step ii), some parts of the sol-gel resin may not be cured and need to be removed to obtain the desired photopatterned structure.

### Step iv)

Step iv) consists in drying the cured sol-gel resin based material. This step may be performed by any conventional methods including notably drying at open air, supercritical CO2 drying, thermal drying, or vacuum drying.

### Photopatterned Structure

In a further aspect, the disclosure relates to a photopatterned structure obtainable according to the method as disclosed hereabove.

The photopatterned is preferably a micro/nanostructured fluidic, optical or photonic device.

### EXAMPLES

### Materials and Methods

APTMS ((3-Acryloxypropyl) trimethoxysilane), 96% Gelest), Lucirin® TPO-L (2,4,6-Trimethylbenzoylphenylphosphinic acid ethyl ester, 95% ABCR), PEG alkoxysilane precursor (N-(Triethoxysilylpropyl)-O-polyethylene oxide urethane, ABCR), TiB (titanium butoxide, Acros Organics) and MAA (methacrylic acid, Acros Organics).

### Example 1

Fast sol-gel processing of organoalkoxysilane precursor: To obtain 6.5 mL of silica-based sol-gel, 10 mL of APTMS precursor and 2.4 mL of dilute hydrochloric acid solution (HCl, pH=3.0) were mixed in a closed round-bottom flask and continuously stirred for 1 hour at 70° C.

A few minutes after magnetic stirring, alkoxysiloxanes insoluble in water were distinguishable in the reaction medium. Then, the mixture became homogeneous when dispersed blocks were solubilized in the alcohol reaction. Simultaneously, an overall increase of viscosity with increasing reaction time was observed due to the polycondensation of produced alkoxysilanol species. In a second step, most of the water and alcohol was removed by distillation with a rotary evaporator under vacuum conditions at 50 mbar and 40° C.

### Preparation of Photoactivable Sol-Gel Resins (Photoresists L1 to L8)

At the end of the fast sol-gel process, photoactive molecules were added to the hydrolyzed APTMS precursor, then the mixture was sonicated for 1 hour at 35° C. The resulting APTMS based photoresist was stored in the refrigerator at 4° C. before further use. No additional volatile solvent was added to the resin. The absence of volatile resin components strongly improved the reproducibility and the repeatability of results of 3D 2P DLW. The prepared photoresists are listed in Table 1.

| Photoresist | L0 | L1 | L2 | L3 | L4 | L5 | L6 | L7 | L8 |
|---|---|---|---|---|---|---|---|---|---|
| PBG1 [mM] | 10 | 0 | 2.5 | 5 | 10 | 15 | 20 | 10 | 10 |
| Lucirin ® TPO-L [mM] | 0 | 10 | 10 | 10 | 10 | 10 | 10 | 20 | 5 |

²⁹Si NMR spectrum of the hydrolyzed APTMS precursor: was recorded on a Bruker DRX 400 MHz spectrometer using standard single-pulse sequences on a 5-mm broadband probe. The relaxation delay was 100 s and measurement were performed at room temperature (298 K) using 300 scans. For obtaining NMR lock signals, deuterated acetone (CD3)2-CO was used as a reference solvent.

UV maskless projection lithography: a commercial system (SmartPrint UV, Microlight3D) based on a digital micromirror device technology (DMD) was used Equipment is composed of a projection system, a motorized X-Y stage and a light-emitting diode (LED) with an emission peak centred at 385 nm used as the light source. Two different objectives were used for projection: (2.5×) and (10× Mitutoyo) for which pixel size corresponds to 2.2 μm and 0.55 μm respectively. The reduction of the total projection field from 5.4 mm×3 mm to 1.3 mm×0.75 mm increases by one order of magnitude the UV light power density from 130 mW-cm⁻² to 2000 mW·cm⁻².

In a typical test, a 1920×1080 bitmap image is transformed into photo patterns and these into control signals for the DMD and the X-Y stage using integrated software. The substrate, a 24 mm×24 mm cover glass slide (0.17±0.01 mm, VWR international), is cleaned before coating to improve photoresist adhesion in a three-step cleaning process with detergent, acetone and isopropyl alcohol. A 20 μL drop of photoresist is deposited using a spiral bar applicator with a film thickness of 20 μm. Then, the sample is placed into the X-Y motorized stage and UV-irradiated. Once photopatterning is completed, the sample is submerged for 15 minutes in a solvent in which the non-irradiated sol-gel photoresist is soluble to obtain the photopatterned film. Neither pre-baking nor post-baking steps are needed to obtain highly cross-linked materials.

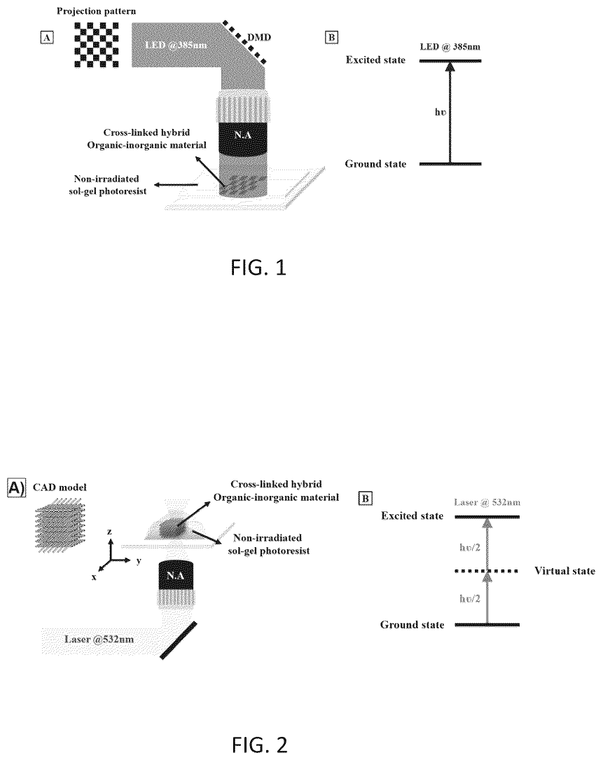

The projection system used for the one-photon induced UV maskless lithography is illustrated by [FIG. 1].

[FIG. 2]A) Schematic of the setup used for the two-photon induced 3D Direct Laser Writing; B) Jablonski diagram of the absorption of light at 532 nm

Two-photon induced 3D Direct Laser Writing (2P DLW): High-resolution 3D printed silica-based microstructures have been fabricated by TPS using a commercial system (μFAB-3D, Microlight3D) as follows: a Nd: YAG pulsed laser beam (repetition rate of 11.7 kHz and a pulse width of 560 ps) centred at 532 nm is focused into a drop of the sol-gel photoresist through a 40× dry microscope objective (N. A=0.95) according to a 3D CAD model. For all experiments, a 5 μL drop of photoresist is deposited on the surface of a cleaned cover-slide. Then, the sample is positioned in a tailor-made sample-holder into the two-photon set-up and covered with a red filter. A motorized piezo-stage allows the sample to be moved along X-Y-Z axes in a volume of 100×100×100 μm³ around the fixed laser beam. A second long-travel motorized linear translation stage allows the sample to be precisely positioned along X and Y axes in replication mode. Once microfabrication is completed, the sample is submerged for 3 minutes in the washing solvent to obtain the 3D printed microstructure. Neither pre-baking nor post-baking steps are used to obtain highly cross-linked materials. Polymerization threshold and damage powers were measured at the entrance pupil of the microscope objective.

[FIG. 2] is a schematic representation of the setup used for the two-photon induced 3D Direct Laser Writing.

### RESULTS

### UV Maskless Projection Lithography

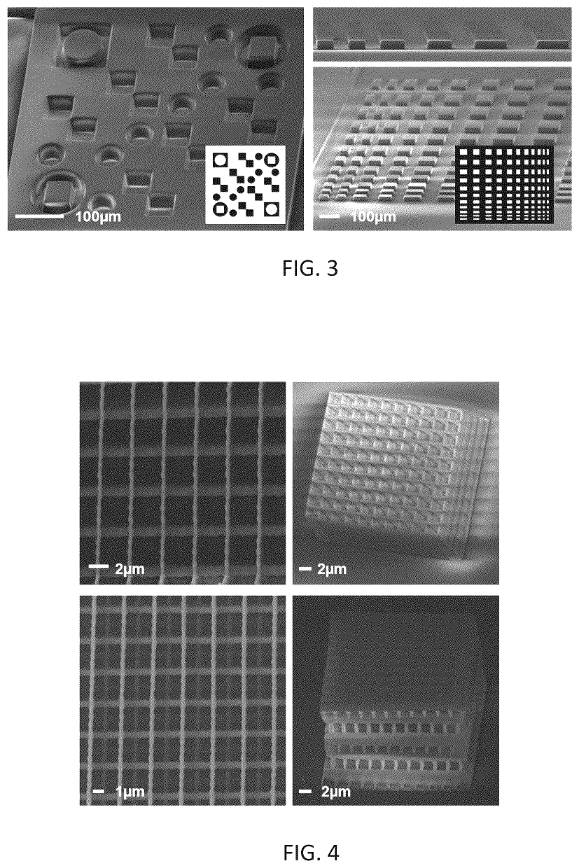

Well-adhered to the substrate photopatterned sol-gel films were fabricated from the photoactivable hybrid organic-inorganic sol-gel resin L7 by UV maskless projection lithography. Photoresist films of 20 μm thickness were UV-irradiated in a single maskless projection step, then they were washed with an organic solvent to obtain crack-free and photopatterned sol-gel films. For example, the solvent washed hybrid sol-gel films in FIG. 1 were obtained by projection of a photomask containing squared and circular features of different sizes and spacing between the features (ranging from 44 μm to 110 μm in length) into the photoactivable hybrid organic-inorganic resin. Two different photomasks were projected on the photoresist for 4 s and 60 s through the 10× and the 2.5× dry microscope objectives to obtain the UV maskless photopatterned sol-gel films in FIGS. 3A and 3B respectively. Under these experimental conditions, the cross-linking of the photoactivable hybrid organic-inorganic sol-gel resin is assumed to proceed by the one-photon induced radical polymerization of double-double carbon bonds (C═C) in the photoresist upon irradiation of the photoinitiator at (λ1).

### 3D Direct Laser Writing

Sol-gel freestanding structures were 3D-printed from the photoactivable hybrid organic-inorganic sol-gel resin L7 by direct laser writing. Woodpile and scaffold structures of less than 20 μm in height were fabricated by the scanning in 3D of the pulsed laser beam in a 5 μL drop of photoresist. The laser beam was focused into the surface of the cover-slide to two-photon polymerized a first layer of two-dimensional and well attached to the substrate sol-gel rods at a constant laser power of 0.6 mW and a constant exposure time of 1 ms using a 40× dry microscope objective. Then, the stacking in the z dimension of sequential layers of 2D sol-gel rods (photopolymerized at the same irradiation conditions) proceeded according to the 3D CAD model of each structure. Solvent washed and 3D-printed scaffold structure in FIG. 2B was fabricated by separating each layer from the previous one by a distance of 1.2 μm in z. In the case of the 3D-printed woodpile structure in FIG. 2D, each layer was shifted laterally (Δl) and vertically (Δz) by a factor (Δz/Δl=1/√2) to obtain a 3D face-centred cubic geometry. Top-view images of the 3D-printed woodpile and scaffold structures are presented in FIG. 4A and FIG. 4C respectively. Under experimental conditions, high-resolution 3D printing is assumed to proceed by a local pH change at the micrometer scale of the reaction medium upon irradiation of the photobase at (A₂).

### Combination of UV Maskless Projection Lithography and 3D Direct Laser Writing

A UV-photopatterned chessboard containing high-resolution 3D pieces was fabricated from a unique sample of photoactivable hybrid organic-inorganic sol-gel resin L7 in a combined two-step printing process. First, a photoresist film of 20 μm thickness was UV-irradiated for 5 s by projecting an optical photomask with a chessboard pattern of 550 m in length through the 10× dry microscope objective. Once one-photon induced UV maskless lithography was completed, a 5 μL drop of photoresist was deposited on the surface of the UV-photopatterned film and the sample was placed directly on the 2P DLW setup without any intermediate washing step. The difference in refractive index between the irradiated and the non-irradiated regions into the photoresist film allowed the positioning of the pulsed laser beam on the appropriate substrate-resin interface to 3D print chess pieces. Knight, pawn and rook pieces of 15 μm in width were fabricated with high precision by two-photon induced 2P DLW on the UV-photopatterned chessboard at a constant laser power of 0.6 mW and a constant exposure time of 1 ms using a 40× dry microscope objective. The UV-photopatterned sol-gel chessboard, the 3D-printed sol-gel chess micro pieces and the resulting sol-gel chess set fabricated by the one-photon and the two-photon induced photopatterning techniques in a two-step process are presented in FIG. 5A, FIG. 5B and FIGS. 5C-5D respectively.

### Example 2

### Formulation of Ti—Si Hybrid Sol-Gel Photoresist

Photoactivatable silicon hybrid resin L4 is formulated in a two-step process: (1) hydrolysis-condensation of APTMS precursor according to a fast sol-gel process as set out in Example 1 and (2) photoactivation of the resulting silicon hybrid sol by addition of both photoinitiator (Lucirin-TPO©) and photobase generator (PBG1) molecules.

Titanium precursor is prepared from a solution of TiB at 70% wt in acetone and MAA. TiB: MAA molar ratio is equal to 1:1. To obtain a photoactivable titanium-silicon hybrid sol-gel resin, the titanium precursor is added to the photoactivatable silicon hybrid sol under magnetic stirring. Titanium precursor to silicon hybrid sol (Ti/Si) molar ratio is between 0.15 and 0.3.

3DLW of photoactivable Ti—Si hybrid sol-gel resin

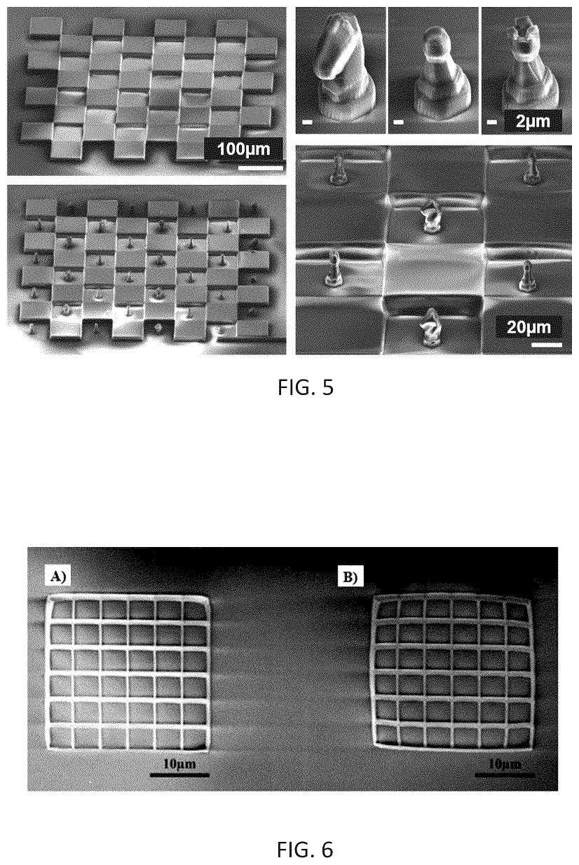

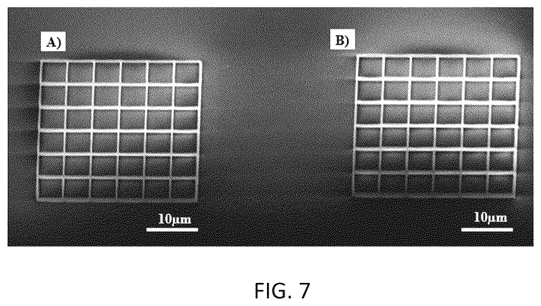

High-resolution woodpile structures of 30 μm in width were fabricated by two-photon induced laser writing. The pulsed laser beam (532 nm) was focused in a 5 μL drop of Ti/Si hybrid sol-gel photoresist into the surface of a cover-slide using a 40× dry microscope objective to obtain well attached to the substrate Ti—Si hybrid sol-gel rods. The woodpile structures in FIG. 6 were obtained from a solution of Ti/Si=0.3 by scanning the pulsed laser beam at a constant laser power of 0.45 mW and a constant exposure time of 5 ms (FIG. 6A) and 10 ms (FIG. 6B), while the woodpile structures in FIG. 7 were obtained from a solution of Ti/Si=0.15 by scanning the pulsed laser beam at a constant laser power of 0.29 mW and a constant exposure time of 10 ms (FIG. 7A) and 20 ms (FIG. 7B).

1-22. (canceled)

23. A photoactivable hybrid organic-inorganic sol-gel resin comprising:
a) A sol-gel resin obtainable by a method comprising the steps of:
a1) hydrolyzing at least one sol-gel precursor, said sol-gel precursor comprising:
an organic polymerizable moiety (A), and
an inorganic polymerizable moiety (B),
and
a2) condensing the obtained hydrolyzed precursor(s); and
b) photoactivators comprising:
a radical photoinitiator, able to initiate a one-photon polymerization at a first irradiation wavelength (λ₁), and
a photobase, able to initiate a two-photon polymerization at a second irradiation wavelength (λ₂),
said photoactivators being homogeneously dispersed in said sol-gel resin a).

24. The photoactivable hybrid organic-inorganic sol-gel resin of claim 23, wherein the inorganic polymerizable moiety (B) is a metal alkoxide group of formula (IB):
M(OR′) (I_{B})
wherein
M is a metal, notably selected from Si, Ti, Zr, Al, Sn; and
R′ is a C₁-C₆ alkyl group.

25. The photoactivable hybrid organic-inorganic sol-gel resin of claim 23, wherein the organic polymerizable moiety (A) is a (meth)acryloyloxy or an epoxy group.

26. The photoactivable hybrid organic-inorganic sol-gel resin of claim 23, wherein the sol-gel precursor is a compound of formula (I):
RₙSi(OR′)₄₋ₙ (I)
wherein:
n is 1, 2 or 3, preferably 1 or 2,
R′ is a C₁-C₆ alkyl group
R is —X-A
X is a C₁-C₆ alkylene group, and
A is an acryloxy, a methacryloxy, an epoxy, or a glycidoxy group.

27. The photoactivable hybrid organic-inorganic sol-gel resin of claim 23, wherein the sol-gel resin is obtainable by a method further comprising a step of:
a3) At least partially removing one or more side products of the hydrolysis-condensation reactions of step a₁) and/or a₂).

28. The photoactivable hybrid organic-inorganic sol-gel resin of claim 23, wherein the sol-gel precursor comprises one or more of acryloxypropyl trimethoxy silane (APTMS), 3-methylacryloxypropyl trimethoxy silane (MAPTMS) tetra(acryloxy-ethoxy)silane, 3-methacryloxypropyl methyldimethoxysilane, 3-methacryloxypropyl methyldiethoxysilane, 3-glycidoxypropyl triethoxysilane, 3-glycidoxypropyl trimethoxysilane, 3-glycidoxypropyl methyldimethoxysilane, or 3-glycidoxypropyl methyldiethoxysilane.

29. The photoactivable hybrid organic-inorganic sol-gel resin of claim 23, wherein the sol-gel resin obtainable after step a₂) has a viscosity superior or equal to 10 cPs.

30. The photoactivable hybrid organic-inorganic sol-gel resin of claim 23, wherein (λ₁) is within a range of emission of a light-emitting diode, a laser or a lamp.

31. The photoactivable hybrid organic-inorganic sol-gel resin of claim 23, wherein the radical photoinitiator comprises a maximum absorption wavelength within a range of emission wavelengths of a light-emitting diode, a laser or a lamp.

32. The photoactivable hybrid organic-inorganic sol-gel resin of claim 23, wherein the radical photoinitiator is an acyl phosphine oxide.

33. The photoactivable hybrid organic-inorganic sol-gel resin of claim 23, wherein the radical photoinitiator is selected from 2,4,6-trimethylbenzoyldiphenyl phosphine oxide, phenylbis(2,4,6-trimethylbenzoyl)phosphine oxide (BAPO).

34. The photoactivable hybrid organic-inorganic sol-gel resin of claim 23, wherein (λ₂) is within a range of emission of a pulsed laser beam.

35. The photoactivable hybrid organic-inorganic sol-gel resin of claim 23, wherein the photobase comprises a maximum absorption wavelength within a range of emission wavelengths of a pulsed laser beam.

36. The photoactivable hybrid organic-inorganic sol-gel resin of claim 23, wherein the photobase releases, when activated, a base having a pKa superior to 11.

37. The photoactivable hybrid organic-inorganic sol-gel resin of claim 36, wherein the released base is selected from DBU (1,8-diazabicyclo [5.4.0]undec-7-ene) or TBD (1,5,7-triazabicyclo[4.4.0]dec-5-ene).

38. The photoactivable hybrid organic-inorganic sol-gel resin of claim 23, wherein the photobase is selected from PBG1 or PBG2.

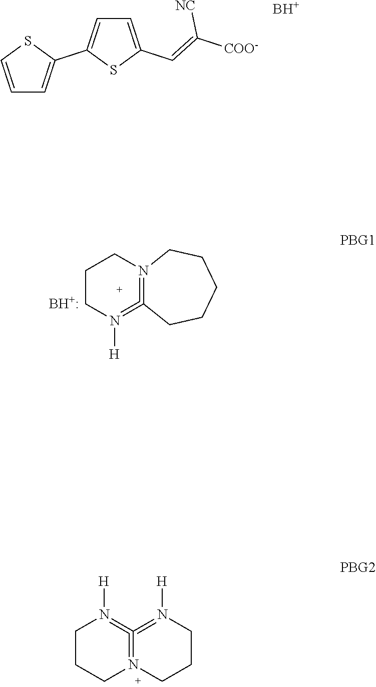

39. A use of a photoactivable hybrid organic-inorganic sol-gel resin according to claim 23 for preparing a photopatterned structure, by 2D and/or 3D photopolymerization, notably by 2D photolithography or by 3D printing.

40. The use of claim 39, wherein the photoactivable hybrid organic-inorganic sol-gel resin is photopatterned by UV maskless projection lithography and/or 3D two-photon direct laser writing (2P DLW).

41. A method for preparing a photopatterned structure from a photoactivable hybrid organic-inorganic sol-gel resin comprising the steps of:
i. providing a photoactivable hybrid organic-inorganic sol-gel resin as defined in claim 23;
ii. photopatterning the sol-gel resin, thereby obtaining a cured sol-gel resin based material,
iii. optionally removing the uncured sol-gel resin, if present; and
iv. recovering the obtained photopatterned structure.

42. The method of claim 41, wherein step ii) comprises the step of irradiating the sol-gel resin at a wavelength:
(λ₁), so as to activate the photoinitiator thereby inducing the cross-linking of the organic polymerizable moiety (A), and/or
(λ₂), so as to activate the photobase thereby inducing the condensation completion of the hydrolyzed polymerizable moiety (B).

43. A photopatterned/3D-printed structure obtainable according to the method of claim 41.

44. The photopatterned/3D-printed structure of claim 43, which is a micro/nano-structured fluidic, optical or photonic device.
